(19) United States
(12) Patent Application Publication
(10) Pub. No.: US 2026/0363073 A1
(43) Pub. Date: Nov. 12, 2026

(54) SYSTEMS AND METHODS FOR POWER SEMICONDUCTOR PACKAGE WITH DUAL ISOLATION LAYER

(71) Applicant: BorgWarner Inc., Auburn Hills, MI (US)

(72) Inventors: Alexandre M.S. REIS, Westfield, IN (US); Celine WONG, Westfield, IN (US)

(73) Assignee: BorgWarner Inc., Auburn Hills, MI (US)

(21) Appl. No.: 19/203,333

(22) Filed: May 9, 2025

(51) Int. Cl. H10W 40/25; H10W 72/30; H10W 90/00

(52) U.S. Cl. CPC H10W 40/255; H10W 72/322; H10W 72/352; H10W 90/736

(57) ABSTRACT

A semiconductor power package includes: a semiconductor die that generates heat configured to be thermally connected to a heatsink through a dual layer of isolation, the dual layer of isolation configured to optimize thermal resistance while maintaining an established thickness between the heatsink and a first device substrate, wherein the dual layer of isolation includes: a first metallic layer configured to be connected to the heatsink; a first ceramic layer connected to the first metallic layer; a second metallic layer connected to the first ceramic layer; a third metallic layer connected to the second metallic layer; a second ceramic layer connected to the third metallic layer; and a fourth metallic layer connected to the second ceramic layer and connected to a device substrate.

### TECHNICAL FIELD

Various embodiments of the present disclosure relate generally to power semiconductor packages and, more particularly, to improving thermal resistance of power semiconductor packages by using dual isolation layers.

### BACKGROUND

In electric vehicles (EV), power semiconductor packages are strategically designed to optimize electrical performance and thermal management. Current developments in EV power electronics, particularly in power converters and on-board chargers (OBCs), place increasing demands on these discrete packages to accommodate higher voltages, greater power densities, and faster switching frequencies. Electrical requirements may decrease thermal performance of the power semiconductor packages.

The present disclosure is directed to overcoming one or more of these above-referenced challenges.

### SUMMARY OF THE DISCLOSURE

In some aspects, the techniques described herein relate to a semiconductor power package including: a semiconductor die that generates heat configured to be thermally connected to a heatsink through a dual layer of isolation, the dual layer of isolation configured to optimize thermal resistance while maintaining an established thickness between the heatsink and a first device substrate, wherein the dual layer of isolation includes: a first metallic layer configured to be connected to the heatsink; a first ceramic layer connected to the first metallic layer; a second metallic layer connected to the first ceramic layer; a third metallic layer connected to the second metallic layer; a second ceramic layer connected to the third metallic layer; and a fourth metallic layer connected to the second ceramic layer and connected to a device substrate.

In some aspects, the techniques described herein relate to a semiconductor power package, wherein the dual layer of isolation further includes one or more adhesive layers.

In some aspects, the techniques described herein relate to a semiconductor power package, wherein the dual layer of isolation further includes one or more sintered layers.

In some aspects, the techniques described herein relate to a semiconductor power package, wherein the one or more sintered layers includes silver (Ag).

In some aspects, the techniques described herein relate to a semiconductor power package, wherein the dual layer of isolation further includes one or more gap filler layers.

In some aspects, the techniques described herein relate to a semiconductor power package, wherein the dual layer of isolation further includes one or more thermal interface materials (TIM).

In some aspects, the techniques described herein relate to a semiconductor power package, wherein the dual layer of isolation has a thermal resistance from approximately 0.2 C/W to approximately 0.33 C/W.

In some aspects, the techniques described herein relate to a semiconductor power package, wherein the dual layer of isolation has a thickness from approximately 1.5 mm to approximately 2.1 mm.

In some aspects, the techniques described herein relate to a semiconductor power package, wherein the dual layer of isolation includes one or more of copper or aluminum.

In some aspects, the techniques described herein relate to a semiconductor power package, wherein the dual layer of isolation includes one or more of aluminum nitride (AlN) or silicon nitride (Si3N4).

In some aspects, the techniques described herein relate to a semiconductor power package, wherein one or more layers of the dual layer of isolation is configured to increase creepage by extending to one or more edges of the first device substrate.

In some aspects, the techniques described herein relate to a semiconductor power package, wherein the heatsink is a cold plate.

In some aspects, the techniques described herein relate to a semiconductor power package, further including: a battery; a power converter including the semiconductor power package, the power converter configured to be connected to the battery; and a motor configured to be connected to the power converter, wherein the battery, the power converter, and the motor are provided as a vehicle.

In some aspects, the techniques described herein relate to a device package including: a device that generates heat configured to be thermally connected to a cold plate through a first ceramic layer, a second ceramic layer, and a first adhesive layer, wherein the first ceramic layer, the second ceramic layer, and first adhesive layers are configured to optimize thermal resistance while maintaining an established thickness between the cold plate and a first device substrate.

In some aspects, the techniques described herein relate to a device package, wherein the first ceramic layer is connected to the first adhesive layer, the first adhesive layer is connected to the second ceramic layer, and the second ceramic layer is connected to the first device substrate via a thermal interface material (TIM) layer, the TIM layer having a thickness from approximately 0.045 mm to approximately 0.07 mm.

In some aspects, the techniques described herein relate to a device package, further including one or more adhesive layers, wherein the one or more adhesive layers has a thickness from approximately 0.03 mm to approximately 0.07 mm.

In some aspects, the techniques described herein relate to a device package, wherein the thermal resistance is from approximately 0.4 C/W and 0.8 C/W and wherein the established thickness is from approximately 0.7 mm to approximately 1.0 mm.

In some aspects, the techniques described herein relate to a device package, wherein the first ceramic layer and the second ceramic layer has a thermal conductivity approximately equal to or greater than 80 W/mK.

In some aspects, the techniques described herein relate to a system including: a package including a power switching device; a heatsink connected to a first side of the package; and a printed circuit board (PCB) connected to a second side of the package, wherein the package is configured to optimize thermal resistance of the system while maintaining an established thickness between the heatsink and the PCB.

In some aspects, the techniques described herein relate to a system, further including a first isolating layer and a second isolating layer.

Additional objects and advantages of the disclosed embodiments will be set forth in part in the description that follows, and in part will be apparent from the description, or may be learned by practice of the disclosed embodiments. The objects and advantages of the disclosed embodiments will be realized and attained by means of the elements and combinations particularly pointed out in the appended claims.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 depicts an exemplary system infrastructure for a vehicle including a power converter, according to one or more embodiments.

FIG. 2 depicts an exemplary system infrastructure for a power converter, according to one or more embodiments.

FIG. 3 depicts an exemplary system infrastructure for a controller, according to one or more embodiments.

FIG. 4 depicts an exemplary dual layer isolation stack, according to one or more embodiments.

FIG. 5 depicts an exemplary dual ceramic layer stack, according to one or more embodiments.

FIG. 6 depicts an exemplary method of assembling the dual layer isolation stack, according to one or more embodiments.

FIG. 7 depicts an exemplary method of assembling the dual ceramic layer stack, according to one or more embodiments.

FIG. 8 depicts exemplary base line dual ceramic layer stacks, according to one or more embodiments.

FIG. 9 depicts exemplary dual ceramic layer stacks with thicker adhesive layers, according to one or more embodiments.

FIG. 10 depicts exemplary dual ceramic layer stacks with thicker TIM layers, according to one or more embodiments.

FIG. 11 depicts exemplary dual ceramic layer stacks with higher K substrates, according to one or more embodiments.

FIG. 12 depicts exemplary base line dual layer isolation stacks, according to one or more embodiments.

FIG. 13 depicts exemplary dual DBA stacks, according to one or more embodiments.

FIG. 14 depicts exemplary dual DBC stacks, according to one or more embodiments.

### DETAILED DESCRIPTION OF EMBODIMENTS

Both the foregoing general description and the following detailed description are exemplary and explanatory only and are not restrictive of the features, as claimed. As used herein, the terms “comprises,” “comprising,” “has,” “having,” “includes,” “including,” or other variations thereof, are intended to cover a non-exclusive inclusion such that a process, method, article, or apparatus that comprises a list of elements does not include only those elements, but may include other elements not expressly listed or inherent to such a process, method, article, or apparatus. In this disclosure, unless stated otherwise, relative terms, such as, for example, “about,” “substantially,” and “approximately” are used to indicate a possible variation of ±10% in the stated value. In this disclosure, unless stated otherwise, any numeric value may include a possible variation of ±10% in the stated value.

The terminology used below may be interpreted in its broadest reasonable manner, even though it is being used in conjunction with a detailed description of certain specific examples of the present disclosure. Indeed, certain terms may even be emphasized below; however, any terminology intended to be interpreted in any restricted manner will be overtly and specifically defined as such in this Detailed Description section. For example, in the context of the disclosure, switching devices may be described as switches or devices, but may refer to any device for controlling the flow of power in an electrical circuit. For example, switches may be metal–oxide–semiconductor field-effect transistors (MOSFETs), bipolar junction transistors (BJTs), insulated-gate bipolar transistors (IGBTs), or relays, for example, or any combination thereof, but are not limited thereto.

Various embodiments of the present disclosure relate generally to power semiconductor packages and, more particularly, to improving thermal resistance of power semiconductor packages by using dual isolation layers.

A power converter, such as a battery charger, for example, according to the disclosure may operate with multiple types of alternating current (AC) input power supplies, including single phase, split/dual/two phase, and three-phase power supplies. The charger may be compatible with a wide range of configurations. An Inductor-Inductor-Capacitor (LLC) converter may be used as a second stage converter using a direct current (DC) link voltage generated from the Power Factor Correction (PFC) as the input voltage for the converter. However, the disclosure is not limited thereto.

The input and output layout of the charger may follow automotive standards. A battery charger according to the disclosure may include a two-stage configuration, including an AC-DC power factor correction converter stage and an isolated DC-DC converter stage. The isolated DC-DC converter may include a full-bridge driver configuration with resonant tank elements to achieve better efficiency. The DC-DC converter may be designed to charge the battery from minimum voltage to maximum voltage. The AC-DC converter may be one or more of a totem pole full bridge, AC-AC matrix, half-bridge (e.g. three legs and six switches), a three-level active neutral-point-clamped, Vienna rectifier, or T-type converter, for example. The DC-DC converter may be one or more of a phase shifted, dual active bridge, CLLLC, or LLC converter, for example.

A power converter according to the disclosure may operate as a battery charger only, or operate bidirectionally for a charging operation or a power supply operation. The converter may either receive power from an AC power source and provide DC power to a battery, or receive power from the battery and provide power as an AC power source. A vehicle to grid (V2G) configuration may be achieved with a designed control strategy for single-phase, two-phase, and three-phase systems. Switches of the battery charger may be any devices, such as GTO, thyristors, or MOSFETs/ IGBTs with series diodes, for example. These switches may also be mechanical components (such as relays or contactors) if sufficient failure rates and arcing conditions during operation are met. Additionally, if the switches are semi-permanent in position, the switches may be implemented as one or more jumper connectors or dual in-line package (DIP) switches.

Electric vehicles, energy storage systems, and backup generators, for example, convert electric power from one form to another. Additionally, an on-board charger for a vehicle, for example, may have a dual purpose. The on-board charger may be a bi-directional system that converts AC voltage to DC voltage in a charging mode (grid-to-battery) and DC voltage to AC voltage in a discharge or inverter mode (battery-to-grid). The charging mode may convert the grid AC into DC voltage to charge the vehicle high voltage (HV) battery, and the discharge or inverter mode may convert the HV battery DC voltage into AC voltage that may be supplied to a load of the grid line voltage, be supplied as a backup generator to power a house when the grid is down, or as an inverter to supply voltage to vehicle AC outlets, for example. The on-board charger may have a two-stage design to meet automotive requirements, with an AC-DC power factor converter in a first stage and an isolated DC-DC converter in a second stage.

Discrete power semiconductor packages play a critical role in EV power converters, inverters, or other power electronic systems. Research has been conducted towards improving the power semiconductor package efficiency. Some solutions may provide power semiconductor packages that offer automation, lower electrical parameters such as inductance, and simpler mechanical clamping. Other solutions may offer better thermal performance with semiconductor packaging design by mounting the semiconductor package directly to a cold plate. Further solutions attempt to combine the advantages of both into one package by offering automaton, improved electrical parameters, simpler mechanical attachment, and direct cooling.

However, ongoing mechanical and electrical challenges persist. A first challenge is to decrease the size of an isolated thermal interface material bond line, which may improve the thermal resistance between a cold plate and a device case across all devices in the system, including all mechanical tolerances. A second challenge is to improve electrical isolation between a live high voltage exposed conductor of the power semiconductor package and a cold plate. The cold plate may include a chassis. Further difficulties arise as attempting to improve the first challenge may lead to creepage and clearance problems due to insufficient electrical isolation, thereby compounding the difficulties in solving the second challenge.

Some solutions may include reinforced isolation layers which may attempt to ensure that the isolation will be intact for the lifetime of the product. However, this solution may increase the cost of the power semiconductor die. The cost may increase exponentially as the die size increases or the on resistance (Rds_on) of the power semiconductor decreases. Additionally, die size may be inversely proportional to Rds_on. The thermal resistance from junction to case (Rth_jc) may be directly proportional to Rds_on. The lower the Rds_on and/or Rth_jc, the larger the device die size.

One or more embodiments may incorporate improved thermal-electrical isolation materials or mechanisms to attach, isolate, and cool the power semiconductor package. In some instances, using a higher Rds_on device with an improved lower thermal resistance electrical isolation layer may decrease system cost. For example, the higher Rds_on device may dissipate more power, heat, leading to an increase in the Rds_on as the device becomes hot. A more efficient thermal path may be employed to remove the additional heat, minimizing the Rds_on increase. As a result, a higher Rds_on device may have the same or better performance as that of a lower Rds_on device, when the thermal path from case to cold plate has a lower thermal resistance or increased efficiency. The power semiconductor package may be located in a system provided as a vehicle. The system may include a battery, a power converter configured to be connected to the battery, a motor configured to be connected to the power converter, and other vehicle elements.

One or more embodiments may provide improved reinforced or dual isolation and a low thermal resistance for a case to cold plate (Rth_ccp) stack, thereby permitting a higher Rds_on device to be used. Optimizing the combination of an Rth_jc stack and an Rth_ccp stack may lead to improved performance and lower system cost. For example, a device with higher Rds_on and a lower Rth_ccp stack may be used in place of a device with lower Rds_on and a higher Rth_ccp stack. Additionally, employing a lower Rth_ccp stack may increase power density. A low Rth_ccp may allow heat to be removed from the power semiconductor device more efficiently and avoid the need to increase power density with parallel devices.

One or more embodiments may achieve dual isolation with low thermal resistance by employing a dual direct bonded copper (DBC) substrate layer or a dual direct bonded aluminum (DBA) substrate layer. The dual layers may be attached via adhesion materials. The selection of the adhesion material and the substrate type (e.g., DBC or DBA) may depend on an established overall stack height and a desired total thermal resistance of the stack. For example, adhesion between the two substrates (e.g., DBC or DBA) and a device may be accomplished by a solder, a sinter (Ag), or a conductive adhesive. Employing dual DBC or DBA layers as described may improve performance, increase efficiency, increase the lifespan of the power semiconductor package and associated electrical devices, lower system costs, while improving creepage and clearance design.

One or more embodiments may achieve dual insulation with low thermal resistance by employing a dual substrate with ceramic material and an adhesion layer between the two substrates. The ceramic material by include aluminum nitride (AlN), aluminum oxide (Al2O3, alumina), silicon nitride (Si3N4), and other ceramics. The adhesion layer may include a conductive adhesive. Optimization of the combination of Rth_jc stack and Rth_ccp stack may lead to better performance and lower system cost, while improving creepage and clearance design.

One or more embodiments may provide isolation layers between a device that generates heat and a cold plate for optimizing a package design. The isolation layers may include a first ceramic layer and a second ceramic layer. The isolation layers may be configured to optimize thermal resistance while maintaining an established thickness between the cold plate and a first device substrate. In some instances, a thermal resistance is from approximately 0.4 C/W to approximately 0.8 C/W and the established thickness is from approximately 0.7 mm to approximately 1.0 mm. In other instances, one or more layers may have a thermal resistance from approximately 0.2 C/W to approximately 0.33 C/W and a thickness from approximately 1.5 mm to approximately 2.1 mm. One or more layers may have a thermal conductivity approximately equal to or greater than 80 W/mK. A first side of the dual isolation layers may be attached to a heatsink via an adhesive layer, and a second side of the dual isolation layers may be attached to a semiconducting layer via, for example, a TIM layer. A first side of the dual isolation layers may be attached to the semiconducting layer via an adhesive layer, and the second side of the dual isolation layers may be attached the heatsink via a TIM layer.

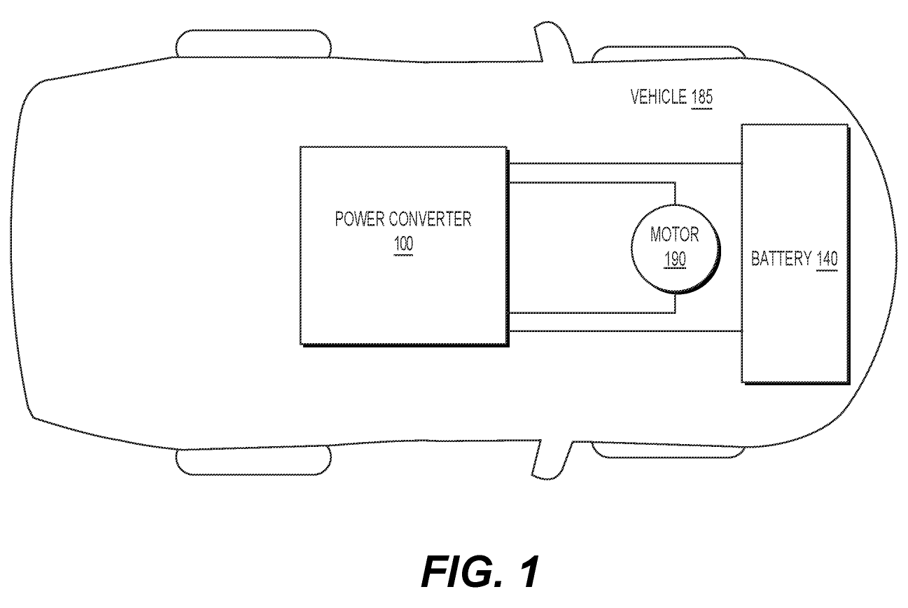

FIG. 1 depicts an exemplary system infrastructure for a vehicle including a power converter, according to one or more embodiments. The power converter 100 may be a combined inverter and converter. Alternatively, the inverter may be an inverter without a converter. In the context of this disclosure, a battery charger, the inverter, the converter, or any combination thereof may be referred to as power converter 100. Electric vehicle 185 may include power converter 100, motor 190, and battery 140. Power converter 100 may include components to receive electrical power from an external source and output electrical power to charge battery 140 of electric vehicle 185. Power converter 100 may convert DC power from battery 140 in electric vehicle 185 to AC power, to drive motor 190 of the electric vehicle 185, for example, but the embodiments are not limited thereto. For example, power converter 100 may include components to receive electrical power from an external source and output electrical power to charge battery 140 without motor 190 connected to power converter 100. Power converter 100 may convert DC power from battery 140 in electric vehicle 185 to AC power, to drive AC components other than motor 190 of the electric vehicle 185. Power converter 100 may be bidirectional, and may convert DC power to AC power, or convert AC power to DC power, such as during regenerative braking, for example. Power converter 100 may be a three-phase inverter, a single-phase inverter, or a multi-phase inverter.

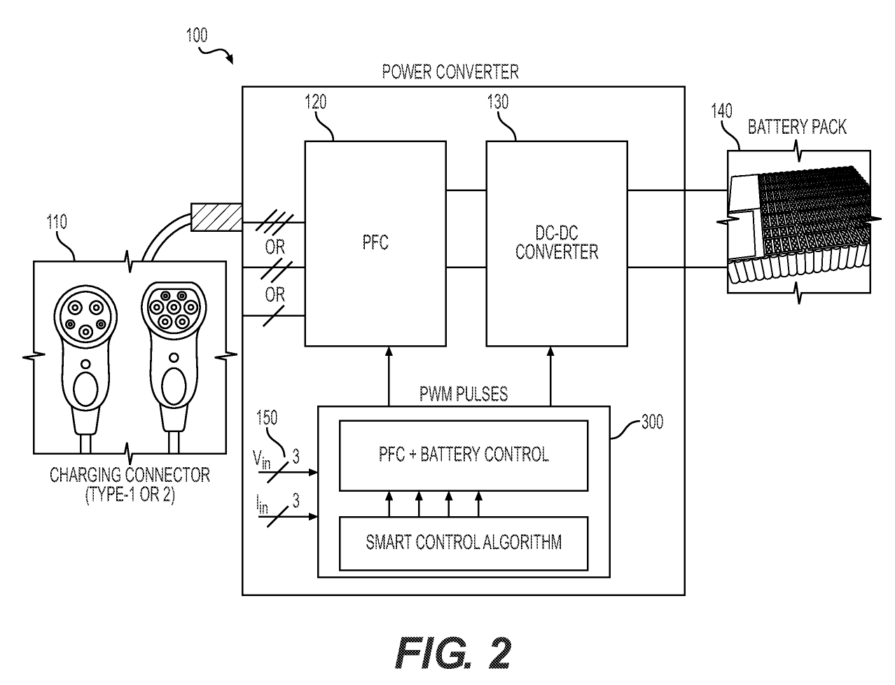

FIG. 2 depicts an exemplary system infrastructure for a battery charger, according to one or more embodiments. Power converter 100 may include or be electrically connectable to a charging connector 110. The charging connector 110 may provide an electrical connection from an external power supply to the power converter 100, and may be a Type 1 or a Type 2 connector, for example. The charging connector 110 may transfer single phase, two-phase, or three phase power.

The power converter 100 may include a Power Factor Correction (PFC) converter as PFC converter 120, a DC-DC converter 130, and a controller 300 receiving signals from input sensor 150. PFC converter 120 may be an AC-DC converter. Controller 300 may include one or more controllers. The power converter 100 may include or be electrically connectable to a battery 140. The power converter 100 may be used in automotive vehicles as an onboard charger to transfer power from an external power source through charging connector 110 to battery 140 in a grid-to-battery operation, or to transfer power from battery 140 in a vehicle to grid configuration (a battery-to-grid operation). The power converter 100 may be included in a system provided as an electric vehicle including a motor configured to rotate based on power received from the battery 140.

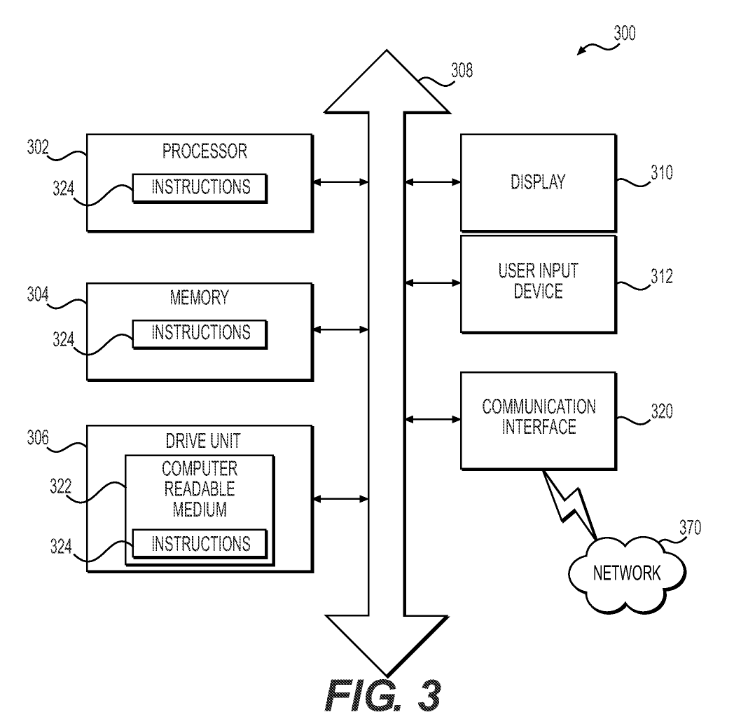

FIG. 3 depicts an exemplary system infrastructure for a controller, according to one or more embodiments. Controller 300 may include one or more controllers.

The controller 300 may include a set of instructions that can be executed to cause the controller 300 to perform any one or more of the methods or computer based functions disclosed herein. The controller 300 may operate as a standalone device or may be connected, e.g., using a network, to other computer systems or peripheral devices.

In a networked deployment, the controller 300 may operate in the capacity of a server or as a client in a server-client user network environment, or as a peer computer system in a peer-to-peer (or distributed) network environment. The controller 300 can also be implemented as or incorporated into various devices, such as a power converter, a personal computer (PC), a tablet PC, a set-top box (STB), a personal digital assistant (PDA), a mobile device, a palmtop computer, a laptop computer, a desktop computer, a communications device, a wireless telephone, a land-line telephone, a control system, a camera, a scanner, a facsimile machine, a printer, a pager, a personal trusted device, a web appliance, a network router, switch or bridge, or any other machine capable of executing a set of instructions (sequential or otherwise) that specify actions to be taken by that machine. In a particular implementation, the controller 300 can be implemented using electronic devices that provide voice, video, or data communication. Further, while the controller 300 is depicted as a single system, the term “system” shall also be taken to include any collection of systems or sub-systems that individually or jointly execute a set, or multiple sets, of instructions to perform one or more computer functions.

As depicted in FIG. 3, the controller 300 may include a processor 302, e.g., a central processing unit (CPU), a graphics processing unit (GPU), or both. The processor 302 may be a component in a variety of systems. The processor 302 may be one or more general processors, digital signal processors, application specific integrated circuits, field programmable gate arrays, servers, networks, digital circuits, analog circuits, combinations thereof, or other now known or later developed devices for analyzing and processing data. The processor 302 may implement a software program, such as code generated manually (i.e., programmed).

The controller 300 may include a memory 304 that can communicate via a bus 308. The memory 304 may be a main memory, a static memory, or a dynamic memory. The memory 304 may include, but is not limited to computer readable storage media such as various types of volatile and non-volatile storage media, including but not limited to random access memory, read-only memory, programmable read-only memory, electrically programmable read-only memory, electrically erasable read-only memory, flash memory, magnetic tape or disk, optical media and the like. In one implementation, the memory 304 includes a cache or random-access memory for the processor 302. In alternative implementations, the memory 304 is separate from the processor 302, such as a cache memory of a processor, the system memory, or other memory. The memory 304 may be an external storage device or database for storing data. Examples include a hard drive, compact disc (“CD”), digital video disc (“DVD”), memory card, memory stick, floppy disc, universal serial bus (“USB”) memory device, or any other device operative to store data. The memory 304 is operable to store instructions executable by the processor 302. The functions, acts or tasks illustrated in the figures or described herein may be performed by the processor 302 executing the instructions stored in the memory 304. The functions, acts or tasks are independent of the particular type of instructions set, storage media, processor or processing strategy and may be performed by software, hardware, integrated circuits, firm-ware, micro-code and the like, operating alone or in combination. Likewise, processing strategies may include multiprocessing, multitasking, parallel processing and the like.

As depicted, the controller 300 may further include a display 310, such as a liquid crystal display (LCD), an organic light emitting diode (OLED), a flat panel display, a solid-state display, a cathode ray tube (CRT), a projector, a printer or other now known or later developed display device for outputting determined information. The display 310 may act as an interface for the user to see the functioning of the processor 302, or specifically as an interface with the software stored in the memory 304 or in the drive unit 306.

Additionally or alternatively, the controller 300 may include an input device 312 configured to allow a user to interact with any of the components of controller 300. The input device 312 may be a number pad, a keyboard, or a cursor control device, such as a mouse, or a joystick, touch screen display, remote control, or any other device operative to interact with the controller 300.

The controller 300 may also or alternatively include drive unit 306 implemented as a disk or optical drive. The drive unit 306 may include a computer-readable medium 322 in which one or more sets of instructions 324, e.g. software, can be embedded. Further, the instructions 324 may embody one or more of the methods or logic as described herein. The instructions 324 may reside completely or partially within the memory 304 and/or within the processor 302 during execution by the controller 300. The memory 304 and the processor 302 also may include computer-readable media as discussed above.

In some systems, a computer-readable medium 322 includes instructions 324 or receives and executes instructions 324 responsive to a propagated signal so that a device connected to a network 370 can communicate voice, video, audio, images, or any other data over the network 370. Further, the instructions 324 may be transmitted or received over the network 370 via a communication port or interface 320, and/or using a bus 308. The communication port or interface 320 may be a part of the processor 302 or may be a separate component. The communication port or interface 320 may be created in software or may be a physical connection in hardware. The communication port or interface 320 may be configured to connect with a network 370, external media, the display 310, or any other components in controller 300, or combinations thereof. The connection with the network 370 may be a physical connection, such as a wired Ethernet connection or may be established wirelessly as discussed below. Likewise, the additional connections with other components of the controller 300 may be physical connections or may be established wirelessly. The network 370 may alternatively be directly connected to a bus 308.

While the computer-readable medium 322 is depicted to be a single medium, the term "computer-readable medium" may include a single medium or multiple media, such as a centralized or distributed database, and/or associated caches and servers that store one or more sets of instructions. The term "computer-readable medium" may also include any medium that is capable of storing, encoding, or carrying a set of instructions for execution by a processor or that cause a computer system to perform any one or more of the methods or operations disclosed herein. The computer-readable medium 322 may be non-transitory, and may be tangible.

The computer-readable medium 322 can include a solid-state memory such as a memory card or other package that houses one or more non-volatile read-only memories. The computer-readable medium 322 can be a random-access memory or other volatile re-writable memory. Additionally or alternatively, the computer-readable medium 322 can include a magneto-optical or optical medium, such as a disk or tapes or other storage device to capture carrier wave signals such as a signal communicated over a transmission medium. A digital file attachment to an e-mail or other self-contained information archive or set of archives may be considered a distribution medium that is a tangible storage medium. Accordingly, the disclosure is considered to include any one or more of a computer-readable medium or a distribution medium and other equivalents and successor media, in which data or instructions may be stored.

In an alternative implementation, dedicated hardware implementations, such as application specific integrated circuits, programmable logic arrays and other hardware devices, can be constructed to implement one or more of the methods described herein. Applications that may include the apparatus and systems of various implementations can broadly include a variety of electronic and computer systems. One or more implementations described herein may implement functions using two or more specific interconnected hardware modules or devices with related control and data signals that can be communicated between and through the modules, or as portions of an application-specific integrated circuit. Accordingly, the present system encompasses software, firmware, and hardware implementations.

The controller 300 may be connected to a network 370. The network 370 may define one or more networks including wired or wireless networks. The wireless network may be a cellular telephone network, an 802.11, 802.16, 802.20, or WiMAX network. Further, such networks may include a public network, such as the Internet, a private network, such as an intranet, or combinations thereof, and may utilize a variety of networking protocols now available or later developed including, but not limited to TCP/IP based networking protocols. The network 370 may include wide area networks (WAN), such as the Internet, local area networks (LAN), campus area networks, metropolitan area networks, a direct connection such as through a Universal Serial Bus (USB) port, or any other networks that may allow for data communication. The network 370 may be configured to couple one computing device to another computing device to enable communication of data between the devices. The network 370 may generally be enabled to employ any form of machine-readable media for communicating information from one device to another. The network 370 may include communication methods by which information may travel between computing devices. The network 370 may be divided into sub-networks. The sub-networks may allow access to all of the other components connected thereto or the sub-networks may restrict access between the components. The network 370 may be regarded as a public or private network connection and may include, for example, a virtual private network or an encryption or other security mechanism employed over the public Internet, or the like.

In accordance with various implementations of the present disclosure, the methods described herein may be implemented by software programs executable by a computer system. Further, in an exemplary, non-limited implementation, implementations can include distributed processing, component or object distributed processing, and parallel processing. Alternatively, virtual computer system processing can be constructed to implement one or more of the methods or functionalities as described herein.

Although the present specification describes components and functions that may be implemented in particular implementations with reference to particular standards and protocols, the disclosure is not limited to such standards and protocols. For example, standards for Internet and other packet switched network transmission (e.g., TCP/IP, UDP/IP, HTML, HTTP) represent examples of the state of the art. Such standards are periodically superseded by faster or more efficient equivalents having essentially the same functions. Accordingly, replacement standards and protocols having the same or similar functions as those disclosed herein are considered equivalents thereof.

It will be understood that the operations of methods discussed are performed in one embodiment by an appropriate processor (or processors) of a processing (i.e., computer) system executing instructions (computer-readable code) stored in storage. It will also be understood that the disclosure is not limited to any particular implementation or programming technique and that the disclosure may be implemented using any appropriate techniques for implementing the functionality described herein. The disclosure is not limited to any particular programming language or operating system.

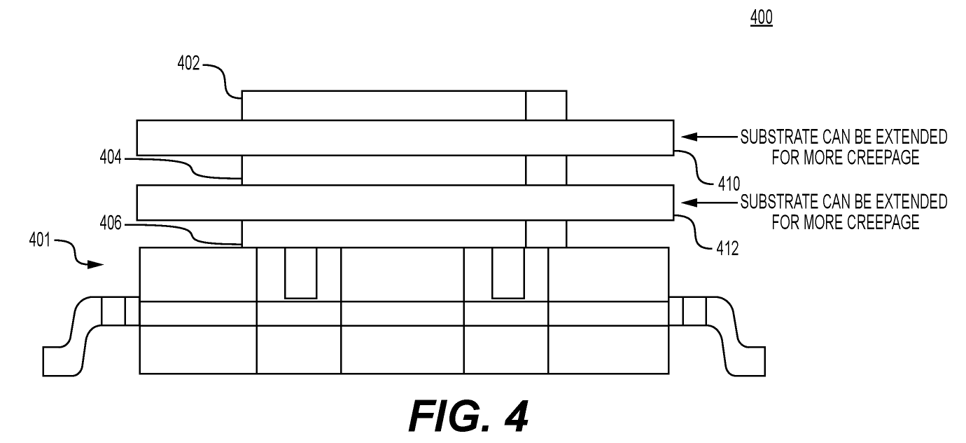

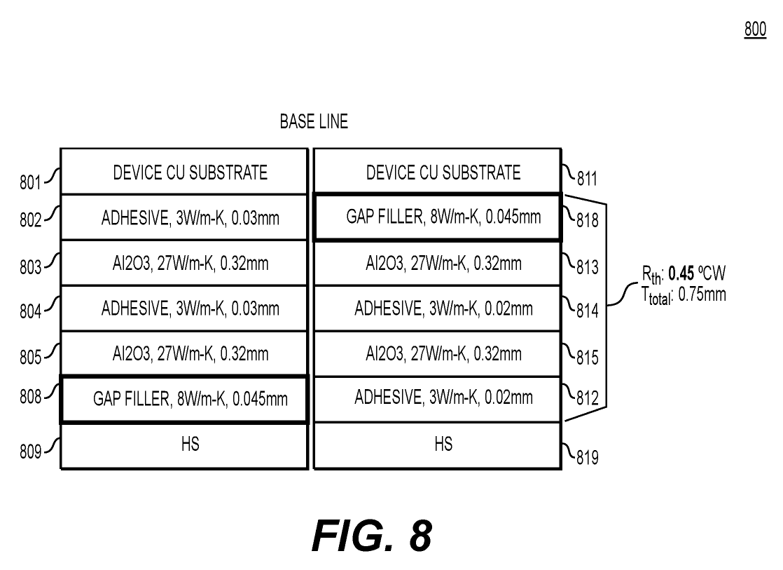

FIG. 4 depicts an exemplary dual layer isolation stack 400, according to one or more embodiments. As depicted in FIG. 4, dual layer isolation stack 400 may include first adhesive layer 402, first substrate 410, second adhesive layer 404, second substrate 412, third adhesive layer 406, and semiconductor 401. Second substrate 412 may be connected to semiconductor 401 via third adhesive layer 406. First substrate 410 may be connected to second substrate 412 via a second adhesive layer 404. First substrate 410 may be connected to a heatsink (not shown) via first adhesive layer 402. First adhesive layer 402 and third adhesive layer 406 may be a conductive layer. For example, the stack depicted in FIG. 4 may be attached to the semiconductor 401 via a thermally conductive layer (e.g., TIM) while the stack may be attached to the a heatsink (not shown) via an adhesive layer, as described below in the discussion of FIG. 8.

Semiconductor 401 may include a discrete semiconducting power package (device package), including one or more semiconducting devices. Semiconductor 401 may be included in PFC converter 120 or DC-DC converter 130, for example. Semiconductor 401 may be included in a power switching device. Semiconductor 401 may be located within a device case. First substrate 410 and second substrate 412 may include one of a DBC layer or DBA layer. First adhesive layer 402, second adhesive layer 404, and third adhesive layer 406 may include a solder, sinter, conductive adhesive, or other adhesive layer.

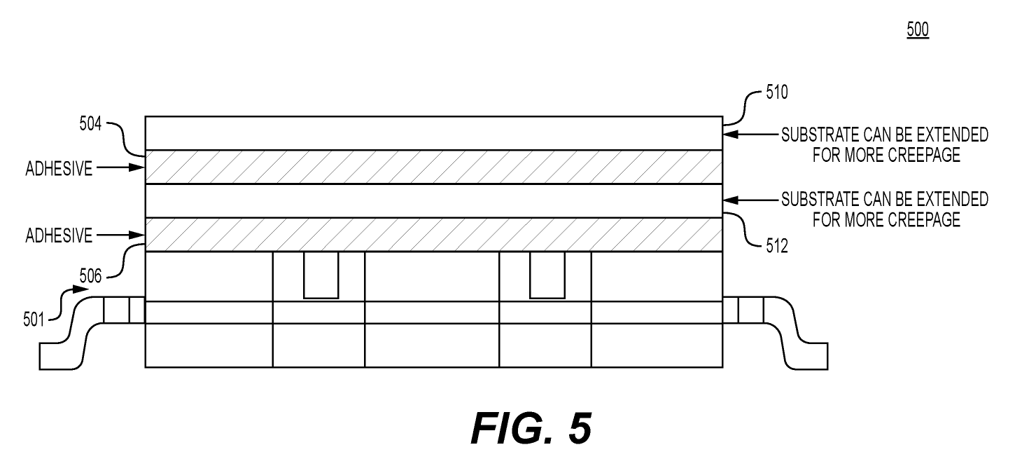

The DBC layer or DBA layer of first substrate 410 and second substrate 412 may include a first metallic layer connected to a first ceramic layer and a second metallic layer connected to the first ceramic layer. The first metallic layer and the second metallic layer of a DBC layer may be copper. The first metallic layer and the second metallic layer of the DBA layer may be aluminum. The first ceramic layer may include a ceramic as described below for first ceramic layer 510 in FIG. 5.

Selecting the materials for first substrate 410 and second substrate 412, semiconductor 401, first adhesive layer 402, second adhesive layer 404, and third adhesive layer 406 may depend on the overall stack height and the total thermal resistance of the dual substrate layer stack, as further described in the discussion of FIGS. 8-14 below. As depicted in FIG. 4, the length of first substrate 410 and second substrate 412 may be extended for additional creepage. For example, the length of first substrate 410 and second substrate412 may extend to one or more edges of a first device substrate of semiconductor 401.

First adhesive layer 402, first substrate 410, second adhesive layer 404, second substrate 412, and third adhesive layer 406 may be located within semiconductor 401. For example, semiconductor 401 may include a semiconductor stack. Third adhesive layer 406 may connect second substrate 412 to the semiconductor stack located within semiconductor 401. First substrate 410 may be connected to second substrate 412 via second adhesive layer 404. First substrate 410 may be connected to a lower surface of a top layer of semiconductor 401. Alternatively, first substrate 410 may be connected to a top surface of a lower layer of semiconductor 401, depending on the design, clearance, and creepage characteristics of semiconductor 401 and its contents.

FIG. 5 depicts an exemplary dual ceramic layer stack 500, according to one or more embodiments. As depicted in FIG. 5, dual ceramic layer stack 500 may include first ceramic layer 510, first adhesive layer 504, second ceramic layer 512, second adhesive layer 506, and semiconductor 501. First adhesive layer 504 may connect first ceramic layer 510 to second ceramic layer 512. Second adhesive layer 506 may connect second ceramic layer 512 to semiconductor 501. Dual ceramic layer stack 500 may be a dual isolation layer stack. For example, first ceramic layer 510 may be a first isolating layer and second ceramic layer 512 may be a second isolating layer.

Semiconductor 501 may be a discrete power semiconducting package (packet), as described above for semiconductor 401 in the description of FIG. 4. First ceramic layer 510 and second ceramic layer 512 may include one or more aluminum nitride (AlN), aluminum oxide (Al2O3, alumina), silicon nitride (Si3N4), or other ceramic material. First adhesive layer 504, and second adhesive layer 506 may be an adhesive as described above for first adhesive layer 402 in the description of FIG. 4.

As depicted in FIG. 5, first ceramic layer 510 and second ceramic layer 512 may be extended to additional creepage. Additionally, first adhesive layer 504 and second adhesive layer 506 may be extended, as depicted in FIG. 5. Dual layer isolation stack 400, as described above in FIG. 4, may achieve lower thermal resistance than dual ceramic layer stack 500. However dual layer isolation stack 400 may require a greater manufacturing cost than dual ceramic layer stack 500. Dual ceramic layer stack 500 may also achieve lower thermal resistance as well as a lower production cost. Both dual layer isolation stack 400 and dual ceramic layer stack 500 may achieve increased performance.

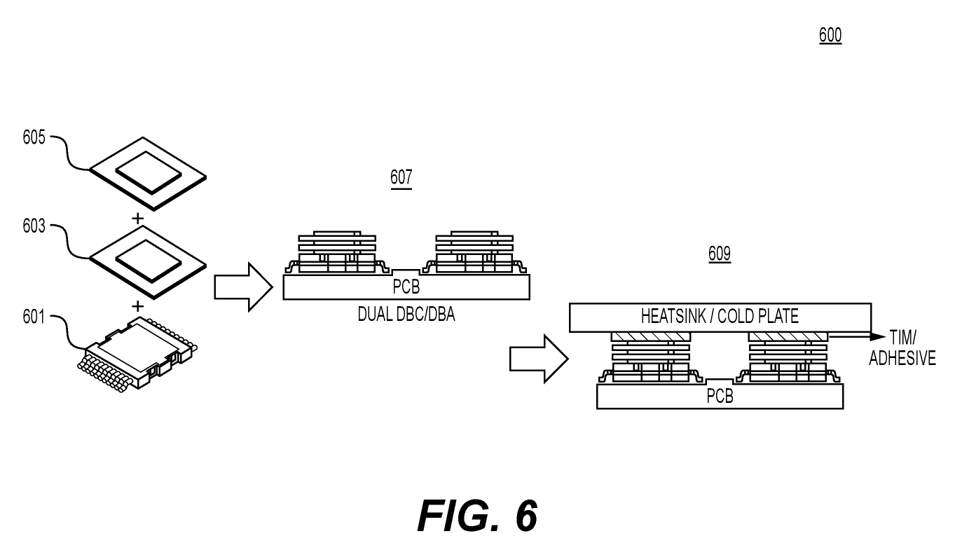

FIG. 6 depicts an exemplary method 600 of assembling a dual layer isolation stack, according to one or more embodiments. As depicted in FIG. 6, semiconductor 601 may be constructed with first layer 603 and second layer 605. Semiconductor 601 may be, for example, semiconductor 401, as described above in the description of FIG. 4. First layer 603 may be, for example, first substrate 410 as described in the description of FIG. 4. Second layer 605 may be, for example, second substrate 412 as described above in the description of FIG. 4. The dual layer isolation stacks may be top side cooled devices (TSC).

At operation 607, one or more stacks of semiconductor 601, first layer 603, and second layer 605 may be assembled as individual stacks on a printed circuit board (PCB) with one or more adhesive layers. The one or more dual layer isolation stacks may be assembled prior to assembly on the PCB or during the operation of assembly on the PCB. Details concerning assembling the individual stacks may be found described above in the description of FIG. 4. At operation 609, the assembled isolation stacks may be attached to a heatsink via an adhesive or a thermal interface material (TIM). The adhesive may include, for example, one or more adhesives as described above for first adhesive layer 402 in the description of FIG. 4. The TIM layer may include, for example, a thermally conductive grease. The heatsink may include a cold plate. For example, first layer 603 and second layer 605 may be first attached to the heatsink with, for example, an adhesive. Following attachment of first layer 603 and second layer 605 to the heatsink, the resulting stack may be attached to the PCB via semiconductor 601.

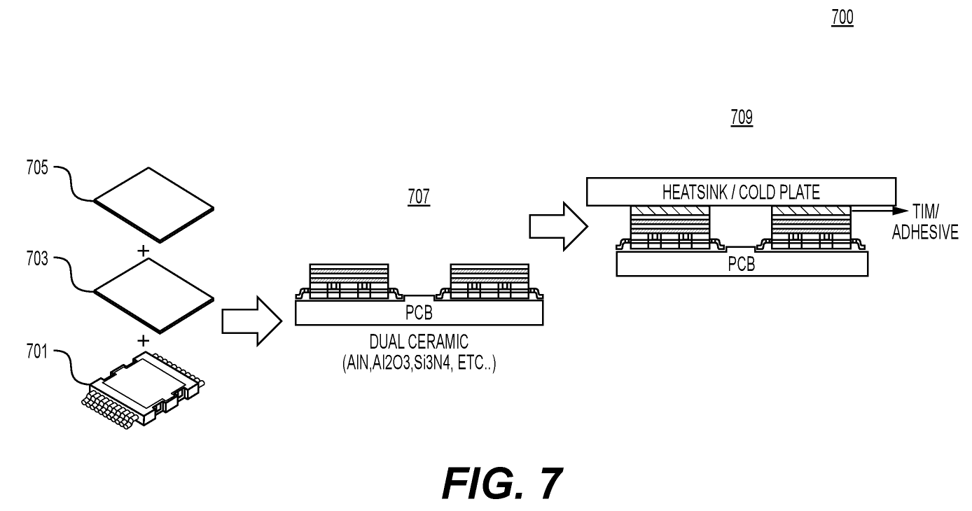

FIG. 7 depicts an exemplary method 700 of assembling a dual ceramic layer stack, according to one or more embodiments. As depicted in FIG. 7, semiconductor 701 may be constructed with first ceramic layer 703 and second ceramic layer 705. First ceramic layer 703 may be, for example, first ceramic layer 510 as described above in the description of FIG. 5. Second ceramic layer 705 may be, for example, second ceramic layer 512 as described above in the description of FIG. 5. The dual ceramic stacks may be top side cooled devices (TSC).

At operation 707, one or more stacks of semiconductor 701, first ceramic layer 703, and second ceramic layer 705 may be assembled as individual stacks on a printed circuit board (PCB) with one or more adhesive layers. Details concerning assembling the individual stacks may be found described above in the description of FIG. 5. The one or more dual ceramic layer stacks may be assembled prior to assembly on the PCB or during the operation of assembly on the PCB. At operation 709, the assembled stacks may be attached to a heatsink via an adhesive or a thermal interface material (TIM). The adhesive may include, for example, one or more adhesives as described above for first adhesive layer 402 in the description of FIG. 4. The heatsink may include a cold plate.

FIG. 8 depicts exemplary base line dual ceramic layer stacks 800, according to one or more embodiments. As depicted in FIG. 8, a first ceramic layer stack may include device substrate layer 801 connected to first adhesive layer 802, first adhesive layer 802 connected to first ceramic layer 803, first ceramic layer 803 connected to second adhesive layer 804, second adhesive layer 804 connected to second ceramic layer 805, second ceramic layer 805 connected to gap filler 808, and gap filler 808 connected to heatsink 809 (HS). A second ceramic layer may include device substrate layer 811, connected to gap filler 818, gap filler 818 connected to first ceramic layer 813, first ceramic layer 813 connected to second adhesive layer 814, second adhesive layer 814 connected to second ceramic layer 815, second ceramic layer 815 connected to first adhesive layer 812, and first adhesive layer 812 connected to heatsink 819 (HS). The two stacks may demonstrate that gap filler layers and first adhesive layers may be used interchangeably. Base line dual ceramic layer stacks 800 may demonstrate high thermal properties while reducing manufacturing cost and improving system efficiency.

Device substrate layer 801 and device substrate layer 811 may include a copper (Cu) or may be, for example, semiconductor 401 as described above in the description of FIG. 4. First adhesive layer 802 and first adhesive layer 812 may include, for example, first adhesive layer 504 as described above in the description of FIG. 5. First ceramic layer 803 and first ceramic layer 813 may include, for example, Al2O3 or may include, for example, first ceramic layer 510 as described above in the description of FIG. 5. Second adhesive layer 804 and second adhesive layer 814 may include, for example, second adhesive layer 506 as described above in the description of FIG. 5. Second ceramic layer 805 and second ceramic layer 815 may include, for example, Al2O3 or may include, for example, second ceramic layer 512 as described above in the description of FIG. 5. Heatsink 809 and heatsink 819 may include, for example, the heatsink described above in the description of FIG. 5.

The materials and thickness of the layers in base line dual ceramic layer stacks 800 may be determined based on a total thickness of the stack and the desired thermal resistance of the stack. For example, as depicted in FIG. 8, the total thermal resistance (Rth) may be approximately 0.45 C/W. The total thickness (Ttotal) of the stack may be approximately 0.75 mm. The thickness of first adhesive layer 802 and first adhesive layer 812 may be approximately 0.03 mm, and the layers may include material having a thermal conductivity of approximately 3 W/mK. The thickness of first ceramic layer 803 and first ceramic layer 813 may be approximately 0.32 mm, and the layers may include material having a thermal conductivity of approximately 27 W/mK. The thickness of second adhesive layer 804 and second adhesive layer 814 may be approximately 0.03 mm, and the layers may include material having a thermal conductivity of approximately 3 W/mK. The thickness of second ceramic layer 805 and second ceramic layer 815 may be approximately 0.32 mm, and the layers may include material having a thermal conductivity of approximately 27 W/mK. The thickness of gap filler 808 and gap filler 818 may be approximately 0.045 mm, and the layers may include material having thermal conductivity of approximately 8 W/mK.

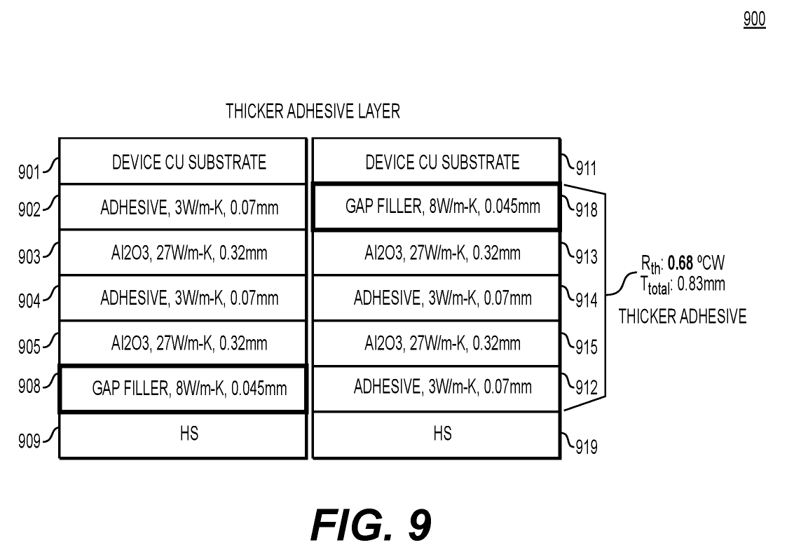

FIG. 9 depicts exemplary dual ceramic layer stacks 900 with thicker adhesive layers, according to one or more embodiments. As depicted in FIG. 9, a first ceramic layer stack may include device substrate layer 901 connected to first adhesive layer 902, first adhesive layer 902 connected to first ceramic layer 903, first ceramic layer 903 connected to second adhesive layer 904, second adhesive layer 904 connected to second ceramic layer 905, second ceramic layer 905 connected to gap filler 908, and gap filler 908 connected to heatsink 909 (HS). A second ceramic layer may include device substrate layer 911, connected to gap filler 918, gap filler 918 connected to first ceramic layer 913, first ceramic layer 913 connected to second adhesive layer 914, second adhesive layer 914 connected to second ceramic layer 915, second ceramic layer 915 connected to first adhesive layer 912, and first adhesive layer 912 connected to heatsink 919 (HS). The two stacks may demonstrate that gap filler layers and first adhesive layers may be used interchangeably. Dual ceramic layer stacks 900 may demonstrate high thermal properties while reducing manufacturing cost and improving system efficiency.

Device substrate layer 901 and device substrate layer 911 may include a copper (Cu) or may be, for example, semiconductor 401 as described above in the description of FIG. 4. First adhesive layer 902 and first adhesive layer 912 may include, for example, first adhesive layer 504 as described above in the description of FIG. 5. First ceramic layer 903 and first ceramic layer 913 may include, for example, Al2O3 or may include, for example, first ceramic layer 510 as described above in the description of FIG. 5. Second adhesive layer 904 and second adhesive layer 914 may include, for example, second adhesive layer 506 as described above in the description of FIG. 5. Second ceramic layer 905 and second ceramic layer 915 may include, for example, Al2O3 or may include, for example, second ceramic layer 512 as described above in the description of FIG. 5. Heatsink 909 and heatsink 919 may include, for example, the heatsink described above in the description of FIG. 5.

The materials and thickness of the layers in dual ceramic layer stacks 900 may be determined based on a total thickness of the stack and the desired thermal resistance of the stack. For example, as depicted in FIG. 9, the total thermal resistance (Rth) may be approximately 0.68 C/W. The total thickness (Ttotal) of the stack may be approximately 0.83 mm. The thickness of first adhesive layer 902 and first adhesive layer 912 may be approximately 0.07 mm, and the layers may include material having a thermal conductivity of approximately 3 W/mK. The thickness of first ceramic layer 903 and first ceramic layer 913 may be approximately 0.32 mm, and the layers may include material having a thermal conductivity of approximately 27 W/mK. The thickness of second adhesive layer 904 and second adhesive layer 914 may be approximately 0.07 mm, and the layers may include material having a thermal conductivity of approximately 3 W/mK. The thickness of second ceramic layer 905 and second ceramic layer 915 may be approximately 0.32 mm, and the layers may include material having a thermal conductivity of approximately 27 W/mK. The thickness of gap filler 908 and gap filler 918 may be approximately 0.045 mm, and the layers may include material having thermal conductivity of approximately 8 W/mK.

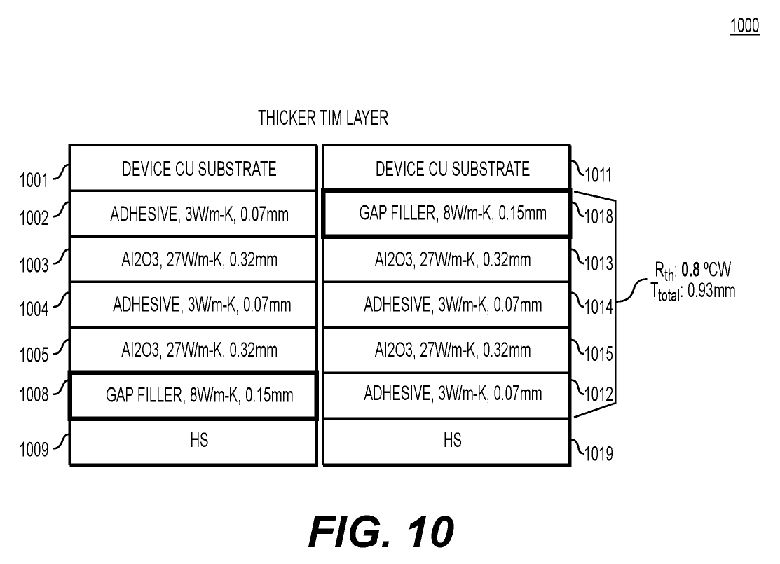

FIG. 10 depicts exemplary dual ceramic layer stacks 1000 with thicker TIM layers, according to one or more embodiments. As depicted in FIG. 10, a first ceramic layer stack may include device substrate layer 1001 connected to first adhesive layer 1002, first adhesive layer 1002 connected to first ceramic layer 1003, first ceramic layer 1003 connected to second adhesive layer 1004, second adhesive layer 1004 connected to second ceramic layer 1005, second ceramic layer 1005 connected to gap filler 1008, and gap filler 1008 connected to heatsink 1009 (HS). A second ceramic layer may include device substrate layer 1011, connected to gap filler 1018, gap filler 1018 connected to first ceramic layer 1013, first ceramic layer 1013 connected to second adhesive layer 1014, second adhesive layer 1014 connected to second ceramic layer 1015, second ceramic layer 1015 connected to first adhesive layer 1012, and first adhesive layer 1012 connected to heatsink 1019 (HS). The two stacks may demonstrate that gap filler layers and first adhesive layers may be used interchangeably. Dual ceramic layer stacks 1000 may demonstrate high thermal properties while reducing manufacturing cost and improving system efficiency.

Device substrate layer 1001 and device substrate layer 1011 may include a copper (Cu) or may be, for example, semiconductor 401 as described above in the description of FIG. 4. First adhesive layer 1002 and first adhesive layer 1012 may include, for example, first adhesive layer 504 as described above in the description of FIG. 5. First ceramic layer 1003 and first ceramic layer 1013 may include, for example, Al2O3 or may include, for example, first ceramic layer 510 as described above in the description of FIG. 5. Second adhesive layer 1004 and second adhesive layer 1014 may include, for example, second adhesive layer 506 as described above in the description of FIG. 5. Second ceramic layer 1005 and second ceramic layer 1015 may include, for example, Al2O3 or may include, for example second ceramic layer 512 as described above in the description of FIG. 5. Heatsink 1009 and heatsink 1019 may include, for example, the heatsink described above in the description of FIG. 5.

The materials and thickness of the layers in dual ceramic layer stacks 1000 may be determined based on a total thickness of the stack and the desired thermal resistance of the stack. For example, as depicted in FIG. 10, the total thermal resistance (Rth) may be approximately 0.8 C/W. The total thickness (Ttotal) of the stack may be approximately 0.93 mm. The thickness of first adhesive layer 1002 and first adhesive layer 1012 may be approximately 0.07 mm, and the layers may include material having a thermal conductivity of approximately 3 W/mK. The thickness of first ceramic layer 1003 and first ceramic layer 1013 may be approximately 0.32 mm, and the layers may include material having a thermal conductivity of approximately 27 W/mK. The thickness of second adhesive layer 1004 and second adhesive layer 1014 may be approximately 0.07 mm, and the layers may include material having a thermal conductivity of approximately 3 W/mK. The thickness of second ceramic layer 1005 and second ceramic layer 1015 may be approximately 0.32 mm, and the layers may include material having a thermal conductivity of approximately 27 W/mK. The thickness of gap filler 1008 and gap filler 1018 may be approximately 0.15 mm, and the layers may include material having thermal conductivity of approximately 8 W/mK. Gap filler 1008 and gap filler 1018 may include, for example, a TIM layer.

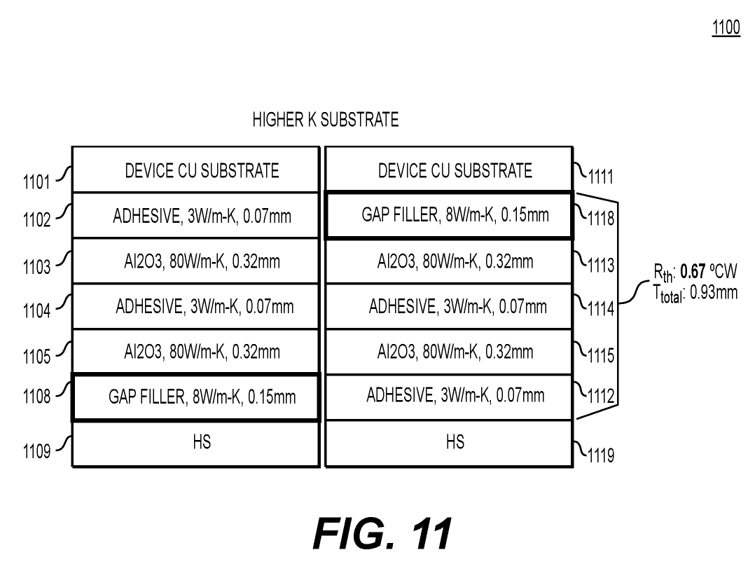

FIG. 11 depicts exemplary dual ceramic layer stacks 1100 with higher K substrates, according to one or more embodiments. As depicted in FIG. 11, a first ceramic layer stack may include device substrate layer 1101 connected to first adhesive layer 1102, first adhesive layer 1102 connected to first ceramic layer 1103, first ceramic layer 1103 connected to second adhesive layer 1104, second adhesive layer 1104 connected to second ceramic layer 1105, second ceramic layer 1105 connected to gap filler 1108, and gap filler 1108 connected to heatsink 1109 (HS). A second ceramic layer may include device substrate layer 1111, connected to gap filler 1118, gap filler 1118 connected to first ceramic layer 1113, first ceramic layer 1113 connected to second adhesive layer 1114, second adhesive layer 1114 connected to second ceramic layer 1115, second ceramic layer 1115 connected to first adhesive layer 1112, and first adhesive layer 1112 connected to heatsink 1119 (HS). The two stacks may demonstrate that the gap filler layers and first adhesive layers may be used interchangeably between the dual ceramic layer stack and the device substrate and between the dual ceramic layer stack and the heatsink. Dual ceramic layer stacks 1100 may demonstrate high thermal properties while reducing manufacturing cost and improving system efficiency.

Device substrate layer 1101 and device substrate layer 1111 may include a copper (Cu) or may be, for example, semiconductor 401 as described above in the description of FIG. 4. First adhesive layer 1102 and first adhesive layer 1112 may include, for example, first adhesive layer 504 as described above in the description of FIG. 5. First ceramic layer 1103 and first ceramic layer 1113 may include, for example, Si3N4 or may include, for example, first ceramic layer 510 as described above in the description of FIG. 5. Second adhesive layer 1104 and second adhesive layer 1114 may include, for example, second adhesive layer 506 as described above in the description of FIG. 5. Second ceramic layer 1105 and second ceramic layer 1115 may include, for example, Si3N4 or may include, for example second ceramic layer 512 as described above in the description of FIG. 5. Heatsink 1109 and heatsink 1119 may include, for example, the heatsink described above in the description of FIG. 5.

The materials and thickness of the layers in dual ceramic layer stacks 1100 may be determined based on a total thickness of the stack and the desired thermal resistance of the stack. For example, as depicted in FIG. 11, the total thermal resistance (Rth) may be approximately 0.67 C/W. The total thickness (Ttotal) of the stack may be approximately 0.93 mm. The thickness of first adhesive layer 1102 and first adhesive layer 1112 may be approximately 0.07 mm, and the layers may include material having a thermal conductivity of approximately 3 W/mK. The thickness of first ceramic layer 1103 and first ceramic layer 1113 may be approximately 0.32 mm, and the layers may include material having a thermal conductivity of approximately 80 W/mK. The thickness of second adhesive layer 1104 and second adhesive layer 1114 may be approximately 0.07 mm, and the layers may include material having a thermal conductivity of approximately 3 W/mK. The thickness of second ceramic layer 1105 and second ceramic layer 1115 may be approximately 0.32 mm, and the layers may include material having thermal conductivity of approximately 80 W/mK. The thickness of gap filler 1108 and gap filler 1118 may be approximately 0.15 mm, and the layers may include material having thermal conductivity of approximately 8 W/mK.

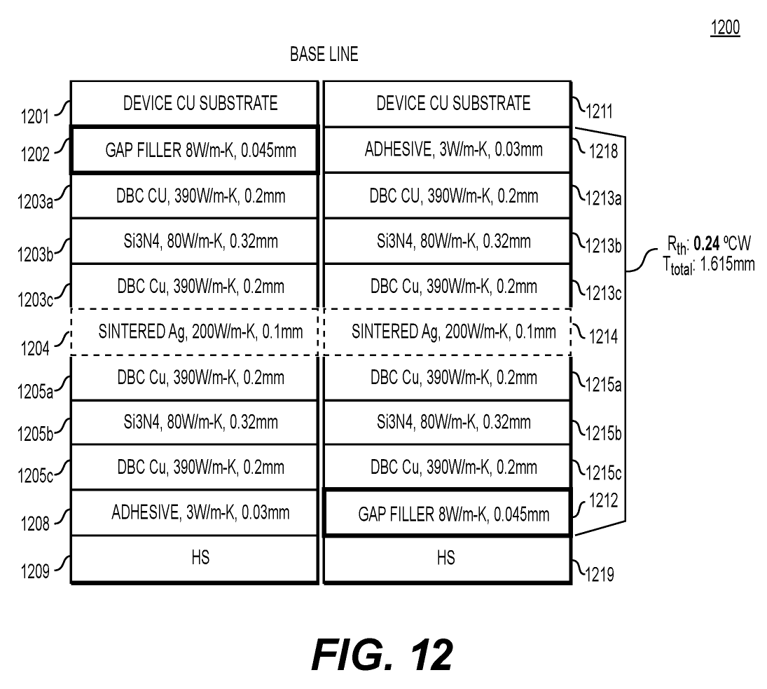

FIG. 12 depicts exemplary base line dual layer isolation stacks 1200, according to one or more embodiments. As depicted in FIG. 12, a first base line dual layer isolation stack may include device substrate layer 1201 connected to gap filler 1202, gap filler 1202 connected to first DBC metallic layer 1203a, first DBC metallic layer 1203a connected to first DBC ceramic layer 1203b, first DBC ceramic layer 1203b connected to second DBC metallic layer 1203c, second DBC metallic layer 1203c connected to first adhesive layer 1204, first adhesive layer 1204 connected to third DBC metallic layer 1205a, third DBC metallic layer 1205a connected to second DBC ceramic layer 1205b, second DBC ceramic layer 1205b connected to fourth DBC metallic layer 1205c, fourth DBC metallic layer 1205c connected to second adhesive layer 1208, and second adhesive layer 1208 connected to heatsink 1209. A second base line dual layer isolation stack may include device substrate layer 1211 connected to second adhesive layer 1218, second adhesive layer 1218 connected to first DBC metallic layer 1213a, first DBC metallic layer 1213a connected to first DBC ceramic layer 1213b, first DBC ceramic layer 1213b connected to second DBC metallic layer 1213c, second DBC metallic layer 1213c connected to first adhesive layer 1214, first adhesive layer 1214 connected to third DBC metallic layer 1215a, third DBC metallic layer 1215a connected to second DBC ceramic layer 1215b, second DBC ceramic layer 1215b connected to fourth DBC metallic layer 1215c, fourth DBC metallic layer 1215c connected to gap filler 1212, and gap filler 1212 connected to heatsink 1219. The base line dual layer isolation stacks may demonstrate that gap filler layers and second adhesive layers may be used interchangeably. Base line dual layer isolation stacks 1200 may demonstrate high thermal properties while reducing manufacturing cost and improving system efficiency.

Device substrate layer 1201 and device substrate layer 1211 may include a copper (Cu) or may be, for example, semiconductor 401 as described above in the description of FIG. 4. First adhesive layer 1204 and first adhesive layer 1214 may include, for example one or more sintered layers of silver (Ag). First adhesive layer 1204, first adhesive layer 1214, second adhesive layer 1208, and second adhesive layer 1218 may include adhesives as described above in the description of FIG. 4. First DBC metallic layer 1203a and first DBC metallic layer 1213a may include copper or other materials associated with first substrate 410 as described above in the description of FIG. 4. First DBC ceramic layer 1203b and first DBC ceramic layer 1213b may include Si3N4 or other materials associated with first substrate 410 as described above in the description of FIG. 4. Second DBC metallic layer 1203c and second DBC metallic layer 1213c may include copper or other materials associated with first substrate 410 as described above in the description of FIG. 4. Third DBC metallic layer 1205a and third DBC metallic layer 1215a may include copper or other materials associated with second substrate 412 as described above in the description of FIG. 4. Second DBC ceramic layer 1205b and second DBC ceramic layer 1215b may include Si3N4 or other materials associated with second substrate 412 as described above in the description of FIG. 4. Fourth DBC metallic layer 1205c and fourth DBC metallic layer 1215c may include copper or other materials associated with second substrate 412 as described above in the description of FIG. 4. Heatsink 1209 and heatsink 1219 may include, for example, the heatsink described above in the description of FIG. 4.

The materials and thickness of the layers in base line dual layer isolation stacks 1200 may be determined based on a total thickness of the stack and the desired thermal resistance of the stack. For example, as depicted in FIG. 12, the total thermal resistance (Rth) may be approximately 0.24 C/W. The total thickness (Ttotal) of the stack may be approximately 1.615 mm. The thickness of gap filler 1202 and gap filler 1212 may be approximately 0.045 mm, and the layers may include material having a thermal conductivity of approximately 8 W/mK. The thickness of first DBC metallic layer 1203a and first DBC metallic layer 1213a may be approximately 0.2 mm, and the layers may include material having a thermal conductivity of approximately 390 W/mK. The thickness of first DBC ceramic layer 1203b and first DBC ceramic layer 1213b may be approximately 0.32 mm, and the layers may include material having a thermal conductivity of approximately 80 W/mK. The thickness of second DBC metallic layer 1203c and second DBC metallic layer 1213c may be approximately 0.2 mm, and the layers may include material having a thermal conductivity of approximately 390 W/mK. The thickness of first adhesive layer 1204 and first adhesive layer 1214 may be approximately 0.01 mm, and the layers may include material having a thermal conductivity of approximately 200 W/mK. The thickness of third DBC metallic layer 1205a and third DBC metallic layer 1215a may be approximately 0.2 mm, and the layers may include material having a thermal conductivity of approximately 390 W/mK. The thickness of second DBC ceramic layer 1205b and second DBC ceramic layer 1215b may be approximately 0.32 mm, and the layers may include material having a thermal conductivity of approximately 80 W/mK. The thickness of fourth DBC metallic layer 1205c and fourth DBC metallic layer 1215c may be approximately 0.2 mm, and the layers may include material having a thermal conductivity of approximately 390 W/mK. The thickness of second adhesive layer 1208 and second adhesive layer 1218 may be approximately 0.03 mm, and the layers may include material having a thermal conductivity of approximately 3 W/mK.

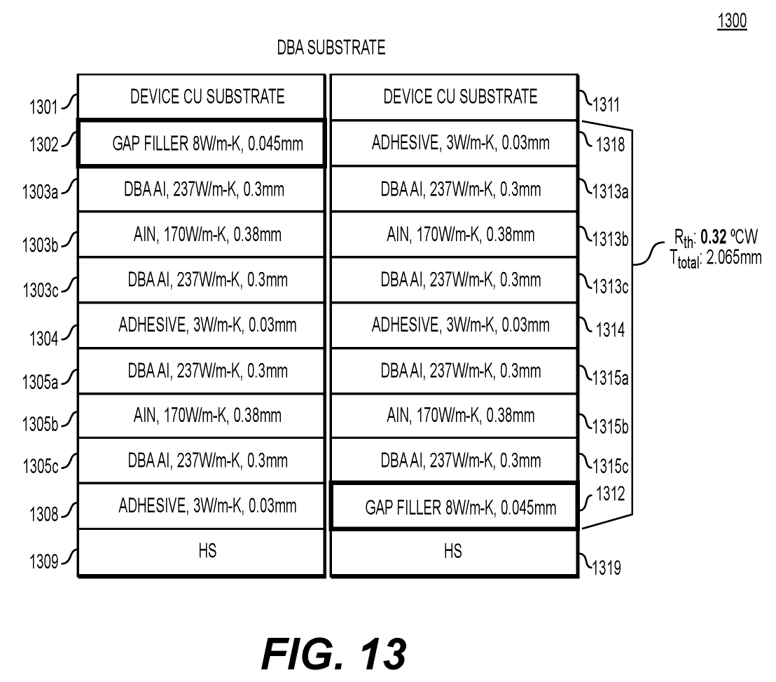

FIG. 13 depicts exemplary dual DBA stacks 1300, according to one or more embodiments. As depicted in FIG. 13, a first DBA stack may include device substrate layer 1301 connected to gap filler 1302, gap filler 1302 connected to first DBA metallic layer 1303a, first DBA metallic layer 1303a connected to first DBA ceramic layer 1303b, first DBA ceramic layer 1303b connected to second DBA metallic layer 1303c, second DBA metallic layer 1303c connected to first adhesive layer 1304, first adhesive layer 1304 connected to third DBA metallic layer 1305a, third DBA metallic layer 1305a connected to second DBA ceramic layer 1305b, second DBA ceramic layer 1305b connected to fourth DBA metallic layer 1305c, fourth DBA metallic layer 1305c connected to second adhesive layer 1308, and second adhesive layer 1308 connected to heatsink 1309. A second dual DBA stack may include device substrate layer 1311 connected to second adhesive layer 1318, second adhesive layer 1318 connected to first DBA metallic layer 1313a, first DBA metallic layer 1313a connected to first DBA ceramic layer 1313b, first DBA ceramic layer 1313b connected to second DBA metallic layer 1313c, second DBA metallic layer 1313c connected to first adhesive layer 1314, first adhesive layer 1314 connected to third DBA metallic layer 1315a, third DBA metallic layer 1315a connected to second DBA ceramic layer 1315b, second DBA ceramic layer 1315b connected to fourth DBA metallic layer 1315c, fourth DBA metallic layer 1315c connected to gap filler 1312, and gap filler 1312 connected to heatsink 1319. Dual DBA stacks 1300 may demonstrate that gap filler layers and the second adhesive layer may be used interchangeably. Dual DBA stacks 1300 may demonstrate high thermal properties while reducing manufacturing cost and improving system efficiency.

Device substrate layer 1301 and device substrate layer 1311 may include a copper (Cu) or may be, for example, semiconductor 401 as described above in the description of FIG. 4. First adhesive layer 1304 and first adhesive layer 1314 may include, for example sintered Ag. First adhesive layer 1304, first adhesive layer 1314, second adhesive layer 1308, and second adhesive layer 1318 may include adhesives as described above in the description of FIG. 4. First DBA metallic layer 1303a and first DBA metallic layer 1313a may include aluminum or other materials associated with first substrate 410 as described above in the description of FIG. 4. First DBA ceramic layer 1303b and first DBA ceramic layer 1313b may include AlN or other materials associated with first substrate 410 as described above in the description of FIG. 4. Second DBA metallic layer 1303c and second DBA metallic layer 1313c may include aluminum or other materials associated with first substrate 410 as described above in the description of FIG. 4. Third DBA metallic layer 1305a and third DBA metallic layer 1315a may include aluminum or other materials associated with second substrate 412 as described above in the description of FIG. 4. Second DBA ceramic layer 1305b and second DBA ceramic layer 1315b may include AlN or other materials associated with second substrate 412 as described above in the description of FIG. 4. Fourth DBA metallic layer 1305c and fourth DBA metallic layer 1315c may include aluminum or other materials associated with second substrate 412 as described above in the description of FIG. 4. Heatsink 1309 and heatsink 1319 may include, for example, the heatsink described above in the description of FIG. 4.

The materials and thickness of the layers in dual DBA stacks 1300 may be determined based on a total thickness of the stack and the desired thermal resistance of the stack. For example, as depicted in FIG. 13, the total thermal resistance (Rth) may be approximately 0.32 C/W. The total thickness (Ttotal) of the stack may be approximately 2.065 mm. The thickness of gap filler 1302 and gap filler 1312 may be approximately 0.045 mm, and the layers may include material having a thermal conductivity of approximately 8 W/mK. The thickness of first DBA metallic layer 1303a and first DBA metallic layer 1313a may be approximately 0.3 mm, and the layers may include material having a thermal conductivity of approximately 237 W/mK. The thickness of first DBA ceramic layer 1303b and first DBA ceramic layer 1313b may be approximately 0.38 mm, and the layers may include material having a thermal conductivity of approximately 170 W/mK. The thickness of second DBA metallic layer 1303c and second DBA metallic layer 1313c may be approximately 0.3 mm, and the layers may include material having a thermal conductivity of approximately 237 W/mK. The thickness of first adhesive layer 1304 and first adhesive layer 1314 may be approximately 0.03 mm, and the layers may include material having a thermal conductivity of approximately 3 W/mK. The thickness of third DBA metallic layer 1305a and third DBA metallic layer 1315a may be approximately 0.3 mm, and the layers may include material having a thermal conductivity of approximately 237 W/mK. The thickness of second DBA ceramic layer 1305b and second DBA ceramic layer 1315b may be approximately 0.38 mm, and the layers may include material having a thermal conductivity of approximately 170 W/mK. The thickness of fourth DBA metallic layer 1305c and fourth DBA metallic layer 1315c may be approximately 0.3 mm, and the layers may include material having a thermal conductivity of approximately 237 W/mK. The thickness of second adhesive layer 1308 and second adhesive layer 1318 may be approximately 0.03 mm, and the layers may include material having a thermal conductivity of approximately 3 W/mK.

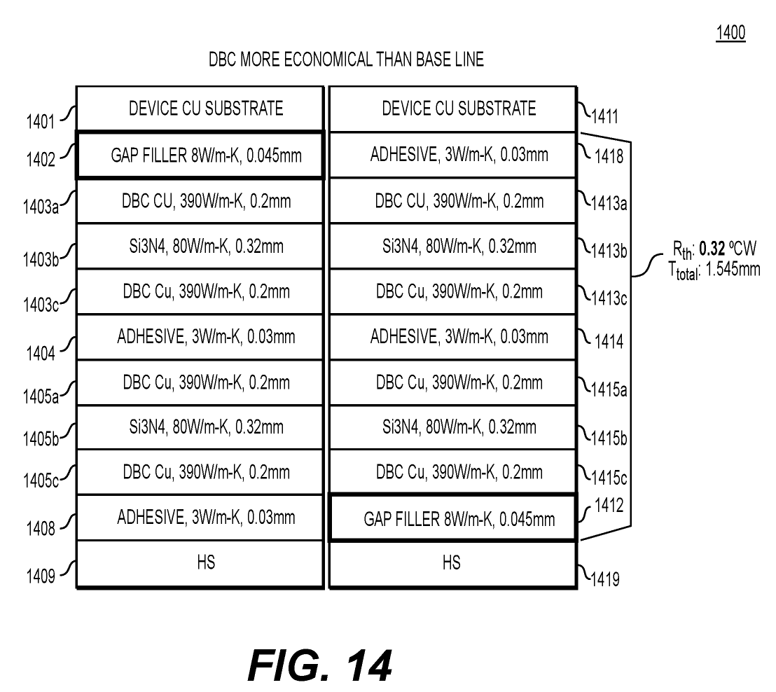

FIG. 14 depicts exemplary dual DBC stacks 1400, according to one or more embodiments. As depicted in FIG. 14, a first DBC stack may include device substrate layer 1401 connected to gap filler 1402, gap filler 1402 connected to first DBC metallic layer 1403a, first DBC metallic layer 1403a connected to first DBC ceramic layer 1403b, first DBC ceramic layer 1403b connected to second DBC metallic layer 1403c, second DBC metallic layer 1403c connected to first adhesive layer 1404, first adhesive layer 1404 connected to third DBC metallic layer 1405a, third DBC metallic layer 1405a connected to second DBC ceramic layer 1405b, second DBC ceramic layer 1405b connected to fourth DBC metallic layer 1405c, fourth DBC metallic layer 1405c connected to second adhesive layer 1408, and second adhesive layer 1408 connected to heatsink 1409. A second base line dual layer isolation stack may include device substrate layer 1411 connected to second adhesive layer 1418, second adhesive layer 1418 connected to first DBC metallic layer 1413a, first DBC metallic layer 1413a connected to first DBC ceramic layer 1413b, first DBC ceramic layer 1413b connected to second DBC metallic layer 1413c, second DBC metallic layer 1413c connected to first adhesive layer 1414, first adhesive layer 1414 connected to third DBC metallic layer 1415a, third DBC metallic layer 1415a connected to second DBC ceramic layer 1415b, second DBC ceramic layer 1415b connected to fourth DBC metallic layer 1415c, fourth DBC metallic layer 1415c connected to gap filler 1412, and gap filler 1412 connected to heatsink 1419. Dual DBC stacks 1400 may demonstrate that the gap filler and the second adhesive layer may be used interchangeably. Dual DBC stacks 1400 may demonstrate high thermal properties while reducing manufacturing cost and improving system efficiency.

Device substrate layer 1401 and device substrate layer 1411 may include a copper (Cu) or may be, for example, semiconductor 401 as described above in the description of FIG. 4. Gap filler 1402 and gap filler 1412 may include, for example, gap filler 808 as described above in the description of FIG. 8. First DBC metallic layer 1403a and first DBC metallic layer 1413a may include copper or other materials associated with second substrate 412 as described above in the description of FIG. 4. First DBC ceramic layer 1403b and first DBC ceramic layer 1413b may include Si3N4 or other materials associated with second substrate 412 as described above in the description of FIG. 4. Second DBC metallic layer 1403c and second DBC metallic layer 1413c may include copper or other materials associated with second substrate 412 as described above in the description of FIG. 4. First adhesive layer 1404 and first adhesive layer 1414 may include an adhesive as described above in the description of FIG. 4. Third DBC metallic layer 1405a and third DBC metallic layer 1415a may include copper or other materials associated with first substrate 410 as described above in the description of FIG. 4. Second DBC ceramic layer 1405b and second DBC ceramic layer 1415b may include Si3N4 or other materials associated with first substrate 410 as described above in the description of FIG. 4. Fourth DBC metallic layer 1405c and fourth DBC metallic layer 1415c may include copper or other materials associated with first substrate 410 as described above in the description of FIG. 4. Heatsink 1409 and heatsink 1419 may include, for example, the heatsink described above in the description of FIG. 4.

The materials and thickness of the layers in dual DBC stacks 1400 may be determined based on a total thickness of the stack and the desired thermal resistance of the stack. For example, as depicted in FIG. 14, the total thermal resistance (Rth) may be approximately 0.32 C/W. The total thickness (Ttotal) of the stack may be approximately 1.545 mm. The thickness of gap filler 1402 and gap filler 1412 may be approximately 0.045 mm, and the layers may include material having a thermal conductivity of approximately 8 W/mK. The thickness of first DBC metallic layer 1403a and first DBC metallic layer 1413a may be approximately 0.2 mm, and the layers may include material having a thermal conductivity of approximately 390 W/mK. The thickness of first DBC ceramic layer 1403b and first DBC ceramic layer 1413b may be approximately 0.32 mm, and the layers may include material having a thermal conductivity of approximately 80 W/mK. The thickness of second DBC metallic layer 1403c and second DBC metallic layer 1413c may be approximately 0.2 mm, and the layers may include material having a thermal conductivity of approximately 390 W/mK. The thickness of first adhesive layer 1404 and first adhesive layer 1414 may be approximately 0.03 mm, and the layers may include material having a thermal conductivity of approximately 3 W/mK. The thickness of third DBC metallic layer 1405a and third DBC metallic layer 1415a may be approximately 0.2 mm, and the layers may include material having a thermal conductivity of approximately 390 W/mK. The thickness of second DBC ceramic layer 1405b and second DBC ceramic layer 1415b may be approximately 0.32 mm, and the layers may include material having a thermal conductivity of approximately 80 W/mK. The thickness of fourth DBC metallic layer 1405c and fourth DBC metallic layer 1415c may be approximately 0.2 mm, and the layers may include material having a thermal conductivity of approximately 390 W/mK. The thickness of second adhesive layer 1408 and second adhesive layer 1418 may be approximately 0.03 mm, and the layers may include material having a thermal conductivity of approximately 3 W/mK.

One or more embodiments may provide a device that generates heat configured to be thermally connected to a cold plate through at least a first ceramic layer, a second ceramic layer, and a first adhesive layer, wherein the first ceramic layer, the second ceramic layer, and first adhesive layers are configured to optimize thermal resistance while maintaining an established thickness between the cold plate and a first device substrate. In some instances, a thermal resistance is from approximately 0.4 C/W to approximately 0.8 C/W and an established thickness is from approximately 0.7 mm to approximately 1.0 mm.

Other examples include one or more layers having a thermal resistance from approximately 0.4 C/W to approximately 0.8 C/W. Further examples include wherein one or more layers may have a and wherein the established thickness is from approximately 0.7 mm to approximately 1.0 mm.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor power package comprising:
a semiconductor die that generates heat configured to be thermally connected to a heatsink through a dual layer of isolation, the dual layer of isolation configured to optimize thermal resistance while maintaining an established thickness between the heatsink and a first device substrate,
wherein the dual layer of isolation includes:
a first metallic layer configured to be connected to the heatsink;
a first ceramic layer connected to the first metallic layer;
a second metallic layer connected to the first ceramic layer;
a third metallic layer connected to the second metallic layer;
a second ceramic layer connected to the third metallic layer; and
a fourth metallic layer connected to the second ceramic layer and connected to a device substrate.

2. The semiconductor power package of claim 1, wherein the dual layer of isolation further includes one or more adhesive layers.

3. The semiconductor power package of claim 1, wherein the dual layer of isolation further includes one or more sintered layers.

4. The semiconductor power package of claim 3, wherein the one or more sintered layers includes silver (Ag).

5. The semiconductor power package of claim 1, wherein the dual layer of isolation further includes one or more gap filler layers.

6. The semiconductor power package of claim 1, wherein the dual layer of isolation further includes one or more thermal interface materials (TIM).

7. The semiconductor power package of claim 1, wherein the dual layer of isolation has a thermal resistance from approximately 0.2 C/W to approximately 0.33 C/W.

8. The semiconductor power package of claim 1, wherein the dual layer of isolation has a thickness from approximately 1.5 mm to approximately 2.1 mm.

9. The semiconductor power package of claim 1, wherein the dual layer of isolation includes one or more of copper or aluminum.

10. The semiconductor power package of claim 1, wherein the dual layer of isolation includes one or more of aluminum nitride (AlN) or silicon nitride (Si3N4).

11. The semiconductor power package of claim 1, wherein one or more layers of the dual layer of isolation is configured to increase creepage by extending to one or more edges of the first device substrate.

12. The semiconductor power package of claim 1, wherein the heatsink is a cold plate.

13. The semiconductor power package of claim 1, further comprising:
a battery;
a power converter including the semiconductor power package, the power converter configured to be connected to the battery; and
a motor configured to be connected to the power converter,
wherein the battery, the power converter, and the motor are provided as a vehicle.

14. A device package comprising:
a device that generates heat configured to be thermally connected to a cold plate through a first ceramic layer, a second ceramic layer, and a first adhesive layer,
wherein the first ceramic layer, the second ceramic layer, and first adhesive layers are configured to optimize thermal resistance while maintaining an established thickness between the cold plate and a first device substrate.

15. The device package of claim 14, wherein the first ceramic layer is connected to the first adhesive layer, the first adhesive layer is connected to the second ceramic layer, and the second ceramic layer is connected to the first device substrate via a thermal interface material (TIM) layer, the TIM layer having a thickness from approximately 0.045 mm to approximately 0.07 mm.

16. The device package of claim 14, further comprising one or more adhesive layers, wherein the one or more adhesive layers has a thickness from approximately 0.03 mm to approximately 0.07 mm.

17. The device package of claim 15, wherein the thermal resistance is from approximately 0.4 C/W and 0.8 C/W and wherein the established thickness is from approximately 0.7 mm to approximately 1.0 mm.

18. The device package of claim 15, wherein the first ceramic layer and the second ceramic layer has a thermal conductivity approximately equal to or greater than 80 W/mK.

19. A system comprising:
a package comprising a power switching device;
a heatsink connected to a first side of the package; and
a printed circuit board (PCB) connected to a second side of the package, wherein the package is configured to optimize thermal resistance of the system while maintaining an established thickness between the heatsink and the PCB.

20. The system of claim 19, further comprising a first isolating layer and a second isolating layer.
